(19) United States
(12) Patent Application Publication
(10) Pub. No.: US 2008/0231681 A1
(43) Pub. Date: Sep. 25, 2008

(54) METHOD OF MANUFACTURING COLOR FILTER

(75) Inventors: Wen-Lung Chen, Hsinchu (TW); Shu-Chin Lee, Hsinchu (TW); Fu-Chuan Tsai, Hsinchu (TW); Wei-Ya Wang, Hsinchu (TW); Yong-Mao Lin, Hsinchu (TW); Chun-Chieh Tsao, Hsinchu (TW)

Correspondence Address: J C PATENTS, INC., 4 VENTURE, SUITE 250, IRVINE, CA, 92618, US

(73) Assignee: AU OPTRONICS CORPORATION, Hsinchu (TW)

(21) Appl. No.: 11/749,584

(22) Filed: May 16, 2007

(30) Foreign Application Priority Data
Mar. 22, 2007 (TW) 96109887

(51) Int. Cl. B41M 3/00; G03F 1/00

(52) U.S. Cl. 347/106; 430/7

(57) ABSTRACT

A method of manufacturing a color filter is provided. First, a substrate is provided and then a partition, for example a black matrix, is formed on the substrate. The black matrix defines a plurality of first color filter areas and a plurality of second color filter areas corresponding to the first color filter areas on the substrate. Thereafter, a first color filter film and a second color filter film are formed in each of the first color filter areas and each of the second color filter areas corresponding thereto, respectively, such that a color filter is provided. The thickness of the first color filter film differs from the thickness of the second color filter film. Thus, images displayed by a transflective liquid crystal display with the aforementioned color filter have even colors.

### CROSS-REFERENCE TO RELATED APPLICATION

This application claims the priority benefit of Taiwan application serial no. 96109887, filed Mar. 22, 2007. All disclosure of the Taiwan application is incorporated herein by reference.

### BACKGROUND OF THE INVENTION

1. Field of the Invention

The present invention generally relates to a method of manufacturing a color filter, in particular, to a method of manufacturing a color filter applied to a transfiective liquid crystal display.

2. Description of Related Art

Because a liquid crystal display is a non self-illuminating display, a liquid crystal display panel must have a light source (for example, a back light source, a front light source or an external light source) for displaying images. According to the manner in which the light source is utilized, liquid crystal displays can be classified into transmissive liquid crystal displays, transflective liquid crystal displays and reflective liquid crystal displays. At present, due to the capacity of a transflective liquid crystal display to utilize light provided by an external light source and a back light source, its usefulness in portable products is gradually accepted.

In general, a conventional transflective liquid crystal display divides its sub pixel area into a transmissive area and a reflective area. The reflective area has a reflective electrode or reflective layer suitable for reflecting an external light source disposed thereon. To produce a multi-color display effect, an color filter is disposed in the transflective liquid crystal display. However, the light from the reflective area will pass through the color filter twice. On the contrary, the light from the transmissive area is directly emitted from the back light source and hence passes through the color filter only once. Consequently, a color mismatch of the image displayed by the reflective area and the transmissive area in a single sub pixel area may occur.

To reduce the foregoing color mismatch problem, the thickness of the color filter films of the color filter can be adjusted to form color filter films of different thickness. The method of adjustment is increasing the thickness of the color filter film corresponding to the transmissive area, or decreasing the thickness of the color filter film corresponding to the reflective area. Therefore, the extent of the adjustment of the color filter films on the light through the transmissive area and the reflective area are almost identical so that color matching is achieved.

FIG. 1A is a side view of a conventional color filter having color filter films of different thickness. As shown in FIG. 1, the color filter 100 includes a first color filter film 122 and a second color filter film 124 both disposed on a substrate 110. The first color filter film 122 is located in a first color filter area I and the second color filter film 124 is located in a second color filter area II. In addition, the first color filter film 122 is almost twice as thick as the first color filter film 124. When the color filter 100 is applied to a transflective liquid crystal display, the first color filter area I corresponds to the location of the transmissive area and the second color filter area II corresponds to the location of the reflective area. As a result, the images displayed by the transmissive area and the reflective area have even colors.

FIG. 1B is a side view showing a method of fabricating the aforementioned first color filter film 122 and the second color filter film 124. As shown in FIG. 1B, a color photoresist layer 140 is formed on the substrate 110 and then the color photoresist layer 140 is exposed using a half-tone mask 150. It can be seen from FIG. 1B that the half-tone mask 150 includes a transparent part 150a that is completely transparent to light and a semi-transparent part 150b that allows only part of the light to pass through. The light passing through the transparent part 150a can fully expose the color photoresist layer 140 while the light passing through the semi-transparent part 150b can partially expose the color photoresist layer 140. Thereafter, the color photoresist layer 140 is developed. Theoretically, if the color photoresist layer 140 is a negative type, for example, the color photoresist layer 140 that has been completely exposed is hardened to form the first color filter film 122, and the color photoresist layer 140 that has been partially exposed is only partly hardened and is partly retained to form the second color filter film 124.

In reality, the idea of obtaining color filter films of different thickness by adjusting the degree of exposure is not easy to implement. According to the foregoing method, when the half-tone mask 150 is used as a mask in an exposure process, the semi-transparent part 150b only allows part of the light to pass through so that the color photoresist layer 140 is only partially exposed (hardened). In general, the photoresist material under the semi-transparent part 150b either completely reacts or does not react with light after being illuminated during the exposure and therefore the degree of exposure cannot be accurately controlled. As a result, the thickness of the color filter films is also difficult to control. In actual operation, the process window of using the method shown in FIG. 1B to fabricate the first color filter film 122 and the second color filter film 124 is very low.

On the other hand, if an etching operation or a multi-exposure operation is used to form color filter films of different thickness, the process will become more complicated and the fabrication cost will be increased. Therefore, it is difficult to fabricate the color filter 100 shown in FIG. 1A without increasing fabrication cost and process steps.

### SUMMARY OF THE INVENTION

Accordingly, the present invention is directed to a method of manufacturing color filter capable of forming color filter films of different thickness in a single sub pixel area without increasing the difficulty of the process.

The present invention is also directed to a method of manufacturing color filter capable of accurately controlling the thickness differences between color filter films in a single sub pixel area.

According to an embodiment of the present invention, a method of manufacturing a color filter is provided. First, a substrate is provided and then a partition is formed on the substrate. The partition defines or forms a plurality of first color filter areas and a plurality of second color filter areas corresponding to the first color filter areas on the substrate. Thereafter, a first color filter film and a second color filter film are formed in each of the first color filter areas and each of the second color filter areas corresponding thereto, respectively. The thickness of the first color filter film differs from the thickness of the second color filter film.

In an embodiment of the present invention, the method of forming the first color filter films and the second color filter films includes performing an ink jet printing process.

In an embodiment of the present invention, the first color filter films and the second color filter films are formed at the same time, for example. More specifically, the method of forming the first color filter films and the second color filter films includes, for example, filling the first color filter areas and the second color filter areas corresponding to the first color filter areas with a first color material and a second color material by means of ink jet printing. Thereafter, the first color material and the second color material inside the first color filter areas and the second color filter areas are dried so as to form the first color filter films and the second color filter films simultaneously. The thickness of the first color filter films and the thickness of the second color filter films are different. Besides, the first color material and the second color material comprise pigment, natural, dye or a combination thereof in same color.

In an embodiment of the present invention, the first color filter films and the second color filter films are formed in sequence. More specifically, the method of forming the first color filter films and the second color filter films includes filling the first color filter areas with a first color material by ink jet printing process and drying the first color material inside the first color filter areas to form the first color filter films. Next, the second color filter areas is filled with a second color material by ink jet printing process and the second color material inside the second color filter areas is dried to form the second color filter films. Besides, the first color material and the second color material comprise pigment, natural, dye or a combination thereof in same color.

In an embodiment of the present invention, the thickness of the first color filter films is almost twice the thickness of the second color filter films. In another embodiment of the present invention, the thickness of the second color filter film is about 40% to about 60% of a thickness of the first color filter film corresponding to the second color filter film and the first color filter film in each of the sub pixel areas has a thickness of about 1 μm to about 2 μm.

In an embodiment of the present invention, the partition comprises a black matrix, and the method further includes performing a hydrophobic treatment on the surface of the partition after forming the partition on the substrate.

In an embodiment of the present invention, the first color filter films and the second color filter films are separated from each other by the partition.

The present invention also provides an alternative method of manufacturing a color filter. First, a substrate is provided and then a partition is formed on the substrate to define or form a plurality of sub pixel areas. Each sub pixel area has a first color filter area and a second color filter area outside or adjacent to the first color filter area. Thereafter, a first color filter film is formed in each of the first color filter areas by performing a first ink jet printing process. After that, a second color filter film is formed inside each of the second color filter areas by performing a second ink jet printing process. The thickness of the first color filter films is different from the thickness of the second color filter films in each sub pixel area.

In an embodiment of the present invention, the first color filter films and the second color filter films are formed in sequence.

In an embodiment of the present invention, the method of forming the first color filter films and the second color filter films includes, for example, performing a first ink jet printing process to fill the first color filter areas with a first color material. Next, the first color material inside the first color filter areas is dried to form the first color filter films. Thereafter, a second ink jet printing process is performed to fill the second color filter areas with the second color material. The volume of the first color material inside the first color filter areas is different from the volume of the second color material inside the second color filter areas. After that, the second color material inside the second color filter areas is dried to form the second color filter films. Besides, the first color material and the second color material comprise pigment, natural, dye or a combination thereof in same color.

In an embodiment of the present invention, the thickness of the first color filter film is almost twice the thickness of the second color filter film in each sub pixel area. In another embodiment of the present invention, the thickness of the second color filter film is about 40% to about 60% of a thickness of the first color filter film corresponding to the second color filter film in each of the sub pixel areas, and the first color filter film in each of the sub pixel areas has a thickness of about 1 μm to about 2 μm.

In an embodiment of the present invention, the method further includes performing a hydrophobic treatment on the surface of the partition after forming the partition on the substrate.

In an embodiment of the present invention, the first color filter film and the second color filter film in each sub pixel area are connected to each other.

The present invention utilizes an ink jet printing process to form color filter films having identical color but different thickness in the single sub pixel area of a color filter. Therefore, uneven image color in the same sub pixel area can be improved when the color filter of the present invention is used in a transflective liquid crystal display. In addition, the method of fabricating the color filter only involves simple steps and the process is easy to control. Therefore, the process window is also improved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a side view of a conventional color filter having color filter films of different thickness.

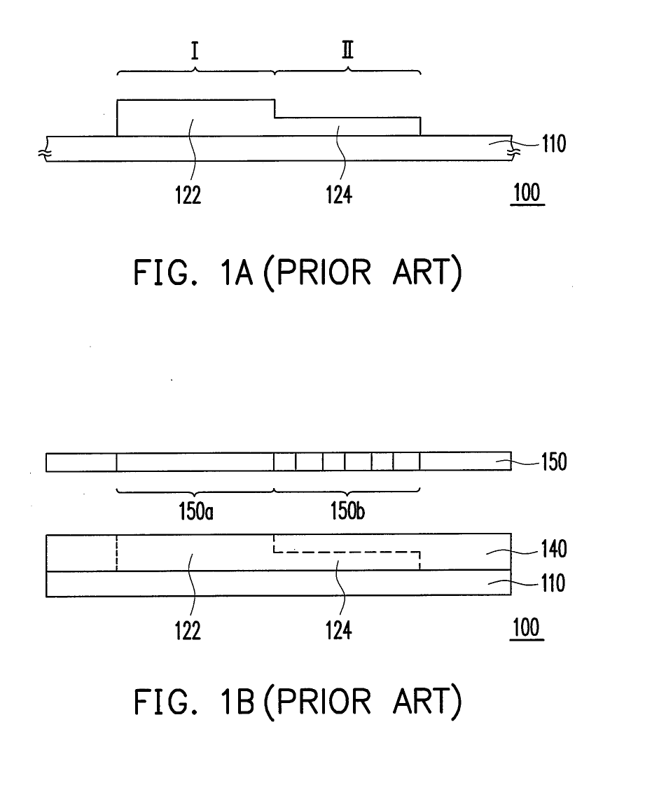

FIG. 1B is a side view showing a conventional method of fabricating a first color filter film and a second color filter film.

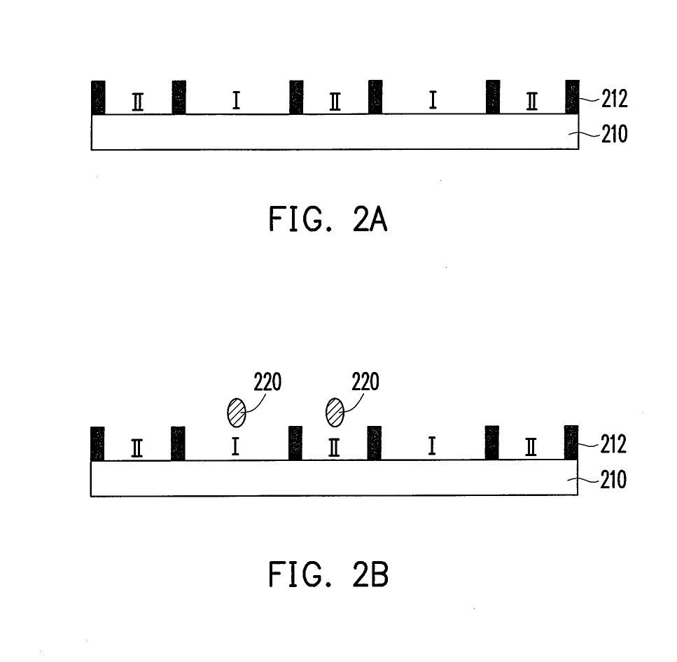

FIGS. 2A to 2C are side views showing a method of fabricating a color filter according to a first embodiment of the present invention.

FIG. 2D is a top view of a color filter according to the first embodiment of the present invention.

FIGS. 3A to 3D are side views showing a method of fabricating a color filter according to a second embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

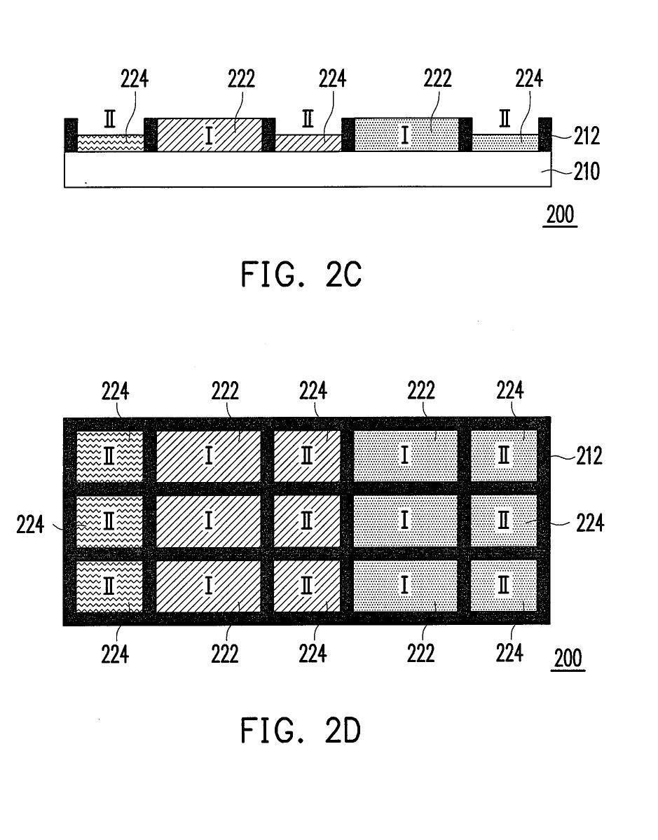

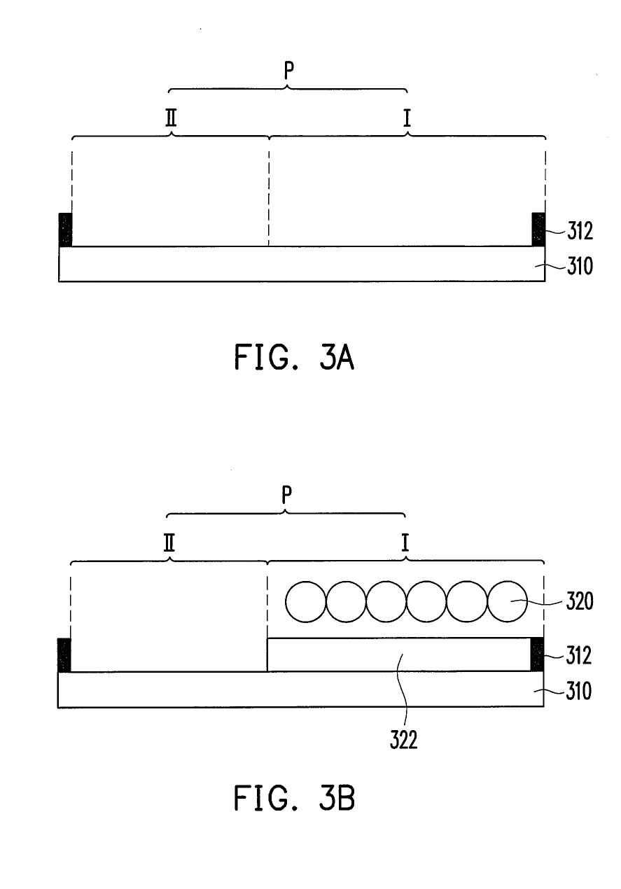

FIGS. 2A to 2C are side views showing a method of fabricating a color filter according to a first embodiment of the present invention. First, as shown in FIG. 2A, a substrate 210 is provided and then a partition, for example, a photoresist partition, a set of embankments or a black matrix is formed on the substrate 210. In the present embodiment, a black matrix 212 is used as an example. The black matrix 212 defines a plurality of first color filter areas I and a plurality of second color filter areas II corresponding to the first color filter areas I on the substrate 210. In general, the substrate 210 is a transparent substrate such as a glass substrate or an amorphous silicon substrate, and the black matrix is a black matrix made of resin, metal or a combination of resin and metal, for example.

Next, as shown in FIG. 2B, an ink jet printing process is performed to fill the interior of the first color filter areas I and the interior of corresponding second color filter areas II with a color material. The color material is pigment, natural, dye or a combination of the above, for example. In the present embodiment, pigment 220 is used as an example. In the ink jet printing process of the present embodiment, the injection volume or quantity of pigment 220 can be adjusted so that the thickness of the pigment 220 inside each of the first color filter areas I is different from the thickness of the pigment 220 inside each of the second filter areas II. It should be noted that the pigment 220 for filling the interior of the first color filter areas I and the pigment 220 for filling the interior of the corresponding second color filter areas II might be the same color. More specifically, each of the first color filter areas I has a corresponding second color filter area II. The pigment 220 that fills the first color filter area I and the pigment 220 that fills the corresponding second color filter area II are of the same color but are filled to different thickness. Furthermore, after forming the black matrix 212 but before performing the ink jet printing process, a hydrophobic treatment on the surface of the black matrix 212 can be performed to prevent the pigment 220 from sputtering in the ink jet printing process and lead to cross contamination.

Thereafter, as shown in FIG. 2C, the pigments 220 inside the first color filter areas I and the second color filter areas II are dried so as to form the first color filter films 222 and the second color filter films 224 simultaneously. At this time, the fabrication of the color filter 200 is almost complete. Because the pigments 220 fill the interior of the first color filter areas I and the second color filter areas II to different thickness, the first color filter films 222 and the second color filter films 224 have different thickness.

According to the present embodiment, the thickness of the first color filter film 222 is greater than the thickness of the second color filter film 224. When the color filter 200 is used in a transfiective liquid crystal display, the first color filter films 222 can be disposed corresponding to the transmissive areas of the transfiective liquid crystal display and the second color filter films 224 can be disposed corresponding to the reflective areas of the transfiective liquid crystal display. Consequently, the images in the transmissive areas and the reflective areas of the transflective liquid crystal display can have more even colors due to the differential thickness between the first color filter films 222 and the second color filter films 224.

More specifically, in a transfiective liquid crystal display, the images displayed by the reflective areas are the result of light passing through the second color filter films 224 twice, and the images display by the transmissive areas are the result of light passing through the first color filter films 222 once. Therefore, if a very close matching between the colors of images displayed by the transmissive areas and the reflective areas is desired, the thickness of the second color filter films 224 should be about 40% to about 60% of the thickness of the first color filter film 222. Preferably, the thickness of the first color filter films 222 is set to twice the thickness of the second color filter films 224. The thickness of the first color filter film 222 can be between about 1 μm to about 2 μm.

However, the present invention is not intended to limit the fabrication in such a way that the first color filter films 222 and the second color filter films 224 have to be fabricated simultaneously. For example, in other embodiment, the first color filter areas I can be filled with pigment 220 first, and then the pigment 220 is dried to form the first color filter films 222. Thereafter, the second color filter areas II are filled with pigment 220, and then the pigment 220 is dried to form the second color filter films 224. Alternatively, the first color filter films 222 are formed after forming the second color filter films 224. In other words, the present invention is not intended to limit the sequence of forming the first color filter films 222 and the second color filter films 224.

FIG. 2D is a top view of a color filter according to the first embodiment of the present invention. As shown in FIGS. 2C and 2D, the color filter 200 of the present embodiment includes a substrate 210, a black matrix 212, a plurality of first color filter films 222 and a plurality of second color filter films 224. The black matrix 212 is disposed on the substrate 210 and defines a plurality of first color filter areas I and a plurality of second color filter areas II corresponding to the first color filter areas I on the substrate 210. In addition, the first color filter films 222 are disposed inside the first color filter areas I and the second color filter films 224 are disposed inside the second color filter areas II.

In the color filter 200, the first color filter films 222 and the corresponding second color filter films 224 are separated from each other by the black matrix 212. Furthermore, the thickness of the first color filter films 222 is different from the thickness of the corresponding second color filter films 224. Yet, the first color filter films 222 and each of the corresponding second color filter films 224 can have the same color, for example, red, green or blue. As a result, the colors of images in the transmissive area and the reflective area of the same pixel of a transflective liquid crystal display having the color filter 200 are more even. In the present embodiment, the first color filter films 222 and each of the corresponding second color filter films 224 can have very similar colors but different colors so that the colors of the images in the transmissive area and the reflective area of the same pixel are more even.

In the present embodiment, the first color filter films 222 and the second color filter films 224 of different thickness are easily fabricated only by controlling the volume or quantity of pigment 220 injected. On the whole, process control is relatively easy and the thickness of the color filter films 222 and 224 can be accurately adjusted. Compared to the conventional photolithographic process, the ink jet printing process used in the present embodiment has a broader tolerance process window.

### Second Embodiment

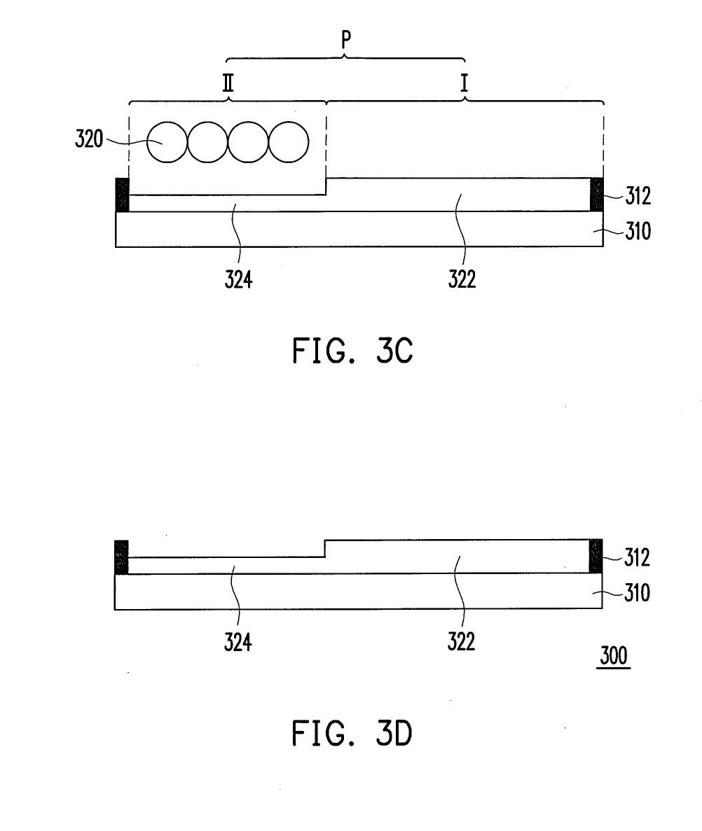

FIGS. 3A to 3D are side views showing a method of fabricating a color filter according to a second embodiment of the present invention. First, as shown in FIG. 3A, a substrate 310 is provided and then a partition, for example, a photoresist partition, a set of embankments or a black matrix is formed on the substrate 310. In the present embodiment, a black matrix 312 is used as an example. The black matrix 312 defines a plurality of sub pixel areas P (only one is shown in the present embodiment). Furthermore, each sub pixel area P has a first color filter area I and a second color filter area II outside the first color filter area I. More specifically, the substrate 310 is a transparent substrate, and the black matrix 312 is a non-transparent black matrix made of resin or metal, for example.

Next, as shown in FIG. 3B, a first color filter film 322 is formed in each of the first color filter areas I by performing a first ink jet printing process. More specifically, the method of forming the first color filter films 322 includes, for example, filling the first color filter areas I with a color material by performing an ink jet printing process. The color material is pigment, natural, dye or a combination of the two. In the present embodiment, pigment 320 is used as an example. Next, the pigment 320 inside the first color filter areas I is dried to form the first color filter films 322. Obviously, a hydrophobic treatment on the surface of the black matrix 312 may be performed after forming the black matrix 312 so as to prevent the pigment 320 from sputtering or diffusing to areas outside the first areas I in the first ink jet printing process.

Thereafter, as shown in FIG. 3C, a second color filter film 324 is formed in each of the second color filter areas II by performing a second ink jet printing process. The thickness of the first color filter film 322 in each sub pixel area P is different from the thickness of the second color filter film 324. The method of forming the second color filter films 324 includes, for example, filling the second color filter areas II with pigment 320 by performing an ink jet printing process and then drying the pigment 320 inside the second color filter areas II. In practice, the pigment 320 that fills the second color filter areas II and the pigment 320 that fills the first color filter areas I are of the same color, for example, read, green or blue.

In performing the first and the second ink jet printing process, the injection volume or quantity of the pigment 320 can be adjusted so that the thickness of the pigment 320 inside the first color filter areas I is different from the thickness of the pigment 320 inside the second filter areas II. Consequently, the thickness of the first color filter films 322 can be different from the thickness of the second color filter films 324. For example, the thickness of the second color filter films 324 is about 40%˜60% of the thickness of the first color filter film 322. Preferably, the thickness of the first color filter films 322 is about twice the thickness of the second color filter films 324. The thickness of the first color filter film 322 can be between about 1 μm to 2 μm. Obviously, in other embodiment, the ratio of thickness between the first color filter films 322 and that of the second color filter films 324 can be suitably adjusted according to the actual requirements of a product.

As shown in FIG. 3D, in the color filter 300 fabricated according to the foregoing steps, the first color filter film 322 and the corresponding second color filter films 324 of different thickness are connected to each other. In other words, each of the first color filter films 322 and the corresponding second color filter film 324 are not separated from each other by the black matrix 312.

In summary, the method of manufacturing the color filter of the present invention has at least the following advantages:

1. Through the ink jet printing process, the present invention is able to fabricate a color filter having color filter films of different thickness quickly and consistently. Hence, it is of great value for reducing the fabrication cost and increasing the productivity.

2. The color filter of the present invention can be applied to a transflective liquid crystal display to prevent the images in the transmissive area and the reflective area from showing color mismatch.

3. The method of manufacturing the color filter of the present invention uses the ink jet printing process to form the color filter films. By adjusting the quantity of ink injected, the thickness of the color filter films can be accurately controlled. In other words, the method of manufacturing the color filter according to the present invention has high process yield.

4. Complicated and hard-to-control processes such as photolithographic process or etching process need not be used for manufacturing the color filter. Therefore, the merits of the present invention include a simple process and a larger process window.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing a color filter, comprising:
providing a substrate;
forming a partition on the substrate to form a plurality of first color filter areas and a plurality of second color filter areas; and
forming a first color filter film and a second color filter film inside at least one of the first color filter areas and at least one of the second color filter areas, respectively, wherein a thickness of the first color filter film is different from that of the second color filter film.

2. The method according to claim 1, wherein the step of forming the first color filter film and/or the second color filter film comprises performing an ink jet printing process.

3. The method according to claim 1, wherein the first color filter film and the second color filter film are formed simultaneously.

4. The method according to claim 1, wherein the step of forming the first color filter film and the second color filter film comprises:
filling the at least one of the first color filter areas with a first color material by performing an ink jet printing process;
filling the at least one of the second color filter areas with a second color material by performing the ink jet printing process; and
drying the first color material and the second color material to form the first color filter film and the second color filter film.

5. The method according to claim 4, wherein the first color material and the second color material comprise pigment, natural, dye or the combination thereof in same color.

6. The method according to claim 1, wherein the first color filter film and the second color filter film are formed in sequence.

7. The method according to claim 1, wherein the step of forming the first color filter film and the second color filter film comprises:
filling the at least one of the first color filter areas with a first color material by performing an ink jet printing process;
drying the first color material to form the first color filter film;
filling the at least one of the second color filter areas with a second color material by performing the ink jet printing process; and
drying the second color material to form the second color filter film.

8. The method according to claim 1, wherein the thickness of the first color filter film is substantially twice that of the second color filter film.

9. The method according to claim 1, wherein the thickness of the second color filter film is about 40% to about 60% of that of the first color filter film.

10. The method according to claim 1, wherein the thickness of first color filter film is about 1 μm to about 2 μm.

11. The method according to claim 1, further comprising performing a hydrophobic treatment on a surface of the partition after forming the partition on the substrate.

12. The method according to claim 1, wherein the first color filter film is separated from the second color filter film by the partition.

13. The method according to claim 1, wherein the partition comprises a black matrix.

14. A method of manufacturing a color filter, comprising:
providing a substrate;
forming a partition on the substrate to form a plurality of sub pixel areas, wherein at least one of the sub pixel areas includes a first color filter area and a second color filter area adjacent to the first color filter area;
forming a first color filter film in the first color filter area by performing a first ink jet printing process; and
forming a second color filter film in the second color filter area by performing a second ink jet printing process, wherein a thickness of the first color filter film is different from that of the second color filter film.

15. The method according to claim 14, wherein the first color filter film and the second color filter film are formed in sequence.

16. The method according to claim 14, wherein the step of forming the first color filter film comprises:
filling the first color filter area with a first color material by performing the first ink jet printing process; and
drying the first color material to form the first color filter film.

17. The method according to claim 16, wherein the first color material comprises pigment, natural, dye or the combination thereof in same color.

18. The method according to claim 14, wherein the thickness of the first color filter film is substantially twice that of the second color filter film.

19. The method according to claim 14, wherein the thickness of the second color filter film is about 40% to about 60% of that of the first color filter film.

20. The method according to claim 14, wherein the thickness of the first color filter film is about 1 μm to about 2 μm.
